(19) United States
(12) Patent Application Publication
(10) Pub. No.: US 2025/0270423 A1
(43) Pub. Date: Aug. 28, 2025

(54) LAMINATED FILM AND METHOD FOR MANUFACTURING SEMICONDUCTOR DEVICE

(71) Applicant: Resonac Corporation, Minato-ku, Tokyo (JP)

(72) Inventors: Akihito IIHOSHI, Minato-ku, Tokyo (JP); Masanobu MIYAHARA, Minato-ku, Tokyo (JP); Makoto SATO, Minato-ku, Tokyo (JP); Daisuke MASUNO, Minato-ku, Tokyo (JP); Ryuta KAWAMATA, TMinato-ku, Tokyo (JP)

(21) Appl. No.: 18/857,452

(22) PCT Filed: Jul. 6, 2023
(86) PCT No.: PCT/JP2023/025165

§ 371 Date: Oct. 17, 2024

(30) Foreign Application Priority Data
Sep. 5, 2022 (JP) 2022-140498

(51) Int. Cl. C09J 7/38; C09J 5/00; C09J 11/06; H01L 21/78; H01L 23/00

(52) U.S. Cl. CPC C09J 7/38; C09J 5/00; C09J 11/06; H01L 21/78; H01L 24/29; H01L 24/83; C09J 2203/326; C09J 2301/208; C09J 2301/408; C09J 2463/00; H01L 2224/2919; H01L 2224/83862

(57) ABSTRACT

A laminated film including: a bonding adhesive layer containing a thermoplastic resin, a thermosetting resin, a curing agent, and a flux compound having two carboxyl groups; an adhesive layer; and a base material layer, in this order, in which the flux compound includes at least one selected from the group consisting of a compound having an aromatic ring, a compound having an aliphatic ring, and a compound having a number of main chain-constituting atoms of 4, 6, or 8 or more.

### TECHNICAL FIELD

The present disclosure relates to a laminated film and a method for producing a semiconductor device.

### BACKGROUND ART

Wire bonding systems of using fine metal wires such as gold wires have been hitherto widely applied to connect semiconductor chips and substrates.

In recent years, in order to respond to the requests for higher functionalization, higher integration, higher speed, and the like for semiconductor devices, a flip-chip connection system (FC connection system) in which a semiconductor chip and a substrate are directly connected by forming conductive protrusions called bumps on the semiconductor chip or the substrate, is becoming widespread.

For example, with regard to the connection between a semiconductor chip and a substrate, a COB (Chip On Board) type connection system that is actively used in BGA (Ball Grid Array), CSP (Chip Size Package), and the like, also falls under the category of the FC connection system. In addition, the FC connection system is also widely used in a COC (Chip On Chip) type connection system in which semiconductor chips are connected to each other by forming connecting parts (for example, bumps or wiring lines) on the semiconductor chips, and a COW (Chip On Wafer) type connection system in which a semiconductor chip and a semiconductor wafer are connected by forming connecting parts (for example, bumps or wiring lines) on the semiconductor wafer (see, for example, Patent Literature 1).

Furthermore, in packages where further size reduction, thickness reduction, and high functionalization are strongly required, chip stack type packages, POP (Package On Package), TSV (Through-Silicon Via), and the like, in which chips are stacked into multi-stages by using the above-mentioned connection systems, are also beginning to become widespread. Since such a technology of stacking into multi-stages allows three-dimensional arrangement of semiconductor chips and the like, packages can be made smaller as compared to techniques of arranging semiconductor chips and the like two-dimensionally. In addition, since the technology of stacking into multi-stages is also effective in improving semiconductor performance, reducing noise, reducing mounting area, and saving electric power, the technology is attracting attention as a next-generation semiconductor wiring technology.

### CITATION LIST

### Patent Literature

Patent Literature 1: Japanese Unexamined Patent Publication No. 2012-222038

### SUMMARY OF INVENTION

### Technical Problem

In recent years, packages used in high-performance mobile equipment and the like are required to have higher density and higher speed, and attention has been paid to three-dimensional packages that use through silicon vias (TSVs), which enable high-speed communication by shortening the conductor wires.

In the above-described packages, the number of semiconductor devices to be stacked tends to increase along with the trend toward higher integration and smaller size. Regarding a method for producing such semiconductor devices, a method of sticking in advance a laminated film in which a film-shaped adhesive and a back grinding tape are laminated, to a semiconductor wafer with bumps, thinning the semiconductor wafer, and then singulating the semiconductor wafer into individual semiconductor chips, is generally used.

Furthermore, in the above-described packages, the distances between bumps are narrowed in order to achieve large capacity and high-speed communication, and accordingly, decrease in embeddability and deterioration in wettability tend to occur. In order to solve this problem, the film-shaped adhesive (bonding adhesive layer) in the above-described laminated film is required to have high fluidity. In order to adapt to packages that respond to such narrow gaps and narrow pitches, laminated films including a bonding adhesive layer that achieves slow curing and high fluidity have been developed. However, when such a laminated film is used after being left to stand in a room temperature environment for a long period of time, at the time of connecting a connecting part of a semiconductor chip to a connecting part of a wiring circuit board, a semiconductor wafer, or another semiconductor chip, there is a problem that wettability of solder to the metal of the connecting parts is likely to deteriorate.

Thus, it is an object of the present disclosure to provide a laminated film that can suppress deterioration of wettability of solder to the metal of connecting parts even when used after being left to stand in a room temperature environment for a long period of time, and a method for producing a semiconductor device.

### Solution to Problem

The inventors of the present invention repeatedly conducted extensive research in order to solve the above-described problems, and as a result, they found that when a laminated film including a bonding adhesive layer that achieves slow curing and high fluidity is used after being left to stand in a room temperature environment for a long period of time, deterioration of wettability of solder to the metal of connecting parts occurs because a flux compound in the bonding adhesive layer migrates to an adhesive layer of a back grinding tape over time. Further, the present inventors found that when research is conducted on the type of a flux compound that can suppress migration over time to the adhesive layer of the back grinding tape, and a specific flux compound is used, even in a case where the laminated film is used after being left to stand in a room temperature environment for a long period of time, deterioration of wettability of solder to the metal of the connecting parts can be suppressed, thus completing the present invention.

That is, the present disclosure provides the following laminated film and the following method for producing a semiconductor device.

[1] A laminated film including, in the following order:
a bonding adhesive layer containing a thermoplastic resin, a thermosetting resin, a curing agent, and a flux compound having two carboxyl groups;
an adhesive layer; and
a base material layer,
wherein the flux compound includes at least one selected from the group consisting of a compound having an aromatic ring, a compound having an aliphatic ring, and a compound having a number of main chain-constituting atoms of 4, 6, or 8 or more.

[2] The laminated film according to the above-described item [1], wherein a number of main chain-constituting atoms of the compound having a number of main chain-constituting atoms of 4, 6, or 8 or more is 4, 6, or 8.

[3] The laminated film according to the above-described item [1] or [2], wherein the compound having a number of main chain-constituting atoms of 4, 6, or 8 or more includes a compound represented by the following general formula (1).

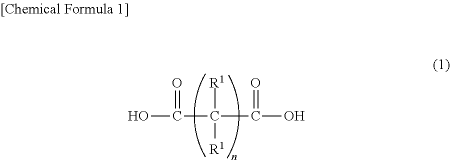

[In formula (1), R¹ represents a hydrogen atom or a monovalent organic group; n represents an integer of 4, 6, or 8 to 14; and a plurality of R¹'s existing therein may be identical with or different from each other.]

[4] The laminated film according to any of the above-described items [1] to [3], wherein the compound having a number of main chain-constituting atoms of 4, 6, or 8 or more includes a compound represented by the following general formula (2).

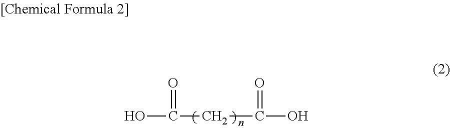

[In formula (2), n represents an integer of 4, 6, or 8 to 14.]

[5] The laminated film according to any of the above-described items [1] to [4], wherein the flux compound has a melting point of 100 to 160° C.

[6] The laminated film according to any of the above-described items [1] to [5], wherein the thermosetting resin includes an epoxy resin.

[7] The laminated film according to any of the above-described items [1] to [6], wherein the curing agent includes an amine-based curing agent.

[8] The laminated film according to any of the above-described items [1] to [7], wherein the curing agent includes an imidazole-based curing agent.

[9] A method for producing a semiconductor device in which respective connecting parts of a semiconductor chip and a wiring circuit board are electrically connected to each other, or a semiconductor device in which respective connecting parts of a plurality of semiconductor chips are electrically connected to each other, the method including:
a step of sticking a surface on the bonding adhesive layer side of the laminated film according to any of the above-described items [1] to [8] and a semiconductor wafer together;
a step of back grinding the semiconductor wafer;
a step of singulating the semiconductor wafer to obtain a bonding adhesive layer-attached semiconductor chip; and
a step of sticking the semiconductor chip to a wiring circuit board, a semiconductor wafer, or another semiconductor chip, with the bonding adhesive layer interposed therebetween.

[10] The method for producing a semiconductor device according to the above-described item [9], wherein the step of sticking the semiconductor chip to a wiring circuit board, a semiconductor wafer, or another semiconductor chip, with the bonding adhesive layer interposed therebetween, including:
a step of arranging a plurality of the other semiconductor chips on a stage; and
a temporary fixing step of sequentially arranging the semiconductor chip on each of the plurality of the other semiconductor chips arranged on the stage, with the bonding adhesive layer interposed therebetween, while heating the stage to 60 to 155° C., and obtaining a plurality of stacked bodies in which the other semiconductor chip, the bonding adhesive layer, and the semiconductor chip are stacked in this order.

[11] The method for producing a semiconductor device according to the above-described item [9], wherein the step of sticking the semiconductor chip to a wiring circuit board, a semiconductor wafer, or another semiconductor chip, with the bonding adhesive layer interposed therebetween, including:
a step of arranging the wiring circuit board or the semiconductor wafer on a stage; and
a temporary fixing step of sequentially arranging a plurality of the semiconductor chips on the wiring circuit board or semiconductor wafer arranged on the stage, with the bonding adhesive layer interposed therebetween, while heating the stage to 60 to 155° C., and obtaining a stacked body in which the wiring circuit board, the bonding adhesive layer, and a plurality of the semiconductor chips are stacked in this order, or a stacked body in which the semiconductor wafer, the bonding adhesive layer, and a plurality of the semiconductor chips are stacked in this order.

### Advantageous Effects of Invention

According to the present disclosure, a laminated film capable of suppressing deterioration of wettability of solder to the metal of a connecting part even when used after being left to stand in a room temperature environment for a long period of time, and a method for producing a semiconductor device can be provided.

### BRIEF DESCRIPTION OF DRAWINGS

FIG. 1 is a schematic cross-sectional view illustrating an embodiment of a laminated film.

FIG. 2 is an FT-IR spectrum of glutaric acid.

FIG. 3 is an FT-IR spectrum of adipic acid.

FIG. 4 is a schematic cross-sectional view illustrating an embodiment of a semiconductor device according to the present disclosure.

FIG. 5 is a schematic cross-sectional view illustrating another embodiment of the semiconductor device according to the present disclosure.

FIG. 6 is a schematic cross-sectional view illustrating another embodiment of the semiconductor device according to the present disclosure.

FIG. 7 is a circuit diagram of the semiconductor chip used for the evaluation of connectivity.

FIG. 8 is ¹H-NMR spectra of a BGT extract obtained from an initial laminated film of Comparative Example 1, a BGT extract obtained from the laminated film of Comparative Example 1 after being left to stand for 4 weeks, and glutaric acid.

FIG. 9 is ¹H-NMR spectra of a BGT extract obtained from an initial laminated film of Example 1, a BGT extract obtained from the laminated film of Example 1 after being left to stand for 4 weeks, and adipic acid.

### DESCRIPTION OF EMBODIMENTS

Hereinafter, embodiments of the present disclosure will be described in detail with reference to the drawings as necessary. In the drawings, the same or equivalent parts are assigned with the same reference numerals, and overlapping descriptions will not be repeated. Furthermore, unless particularly stated otherwise, the positional relationships such as upper, lower, right, and left are based on the positional relationships shown in the drawings. In addition, the dimensional ratios in the drawings are not limited to the ratios shown in the drawings.

Upper limit values and lower limit values of numerical value ranges described individually can be combined arbitrarily. The numerical values described in the Examples can also be used as the upper limit values or lower limit values of numerical value ranges. In the present specification, the term “(meth)acryl” means acryl or methacryl corresponding thereto.

### <Laminated Film>

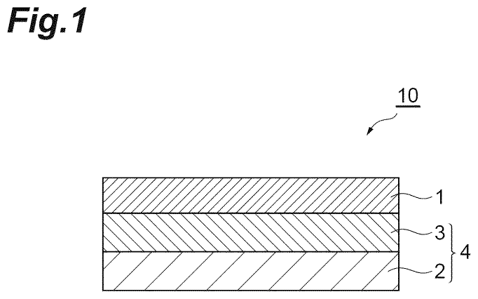

FIG. 1 is a schematic cross-sectional view illustrating an embodiment of a laminated film according to the present disclosure. As shown in FIG. 1, the laminated film 10 according to the present embodiment includes a bonding adhesive layer (film-shaped adhesive) 1, and a back grinding tape 4 composed of a base material layer 2 and an adhesive layer 3. The laminated film may also include a base material film on a surface of the bonding adhesive layer 1 on the opposite side from the adhesive layer 3.

(Bonding adhesive layer 1)

The bonding adhesive layer contains (a) a thermoplastic resin (hereinafter, optionally referred to as “component (a)”), (b) a thermosetting resin (hereinafter, optionally referred to as “component (b)”), (c) a curing agent (hereinafter, optionally referred to as “component (c)”), and (d) a flux compound having two carboxyl groups (hereinafter, optionally referred to as “component (d)”). The bonding adhesive layer may further contain (e) a filler (hereinafter, optionally referred to as “component (e)”).

Each component constituting the bonding adhesive layer will be described below.

### (a) Thermoplastic Resin

The component (a) is not particularly limited; however, examples thereof include a phenoxy resin, a polyimide resin, a polyamide resin, a polycarbodiimide resin, a cyanate ester resin, an acrylic resin, a polyester resin, a polyethylene resin, a polyether sulfone resin, a polyetherimide resin, a polyvinyl acetal resin, a urethane resin, and an acrylic rubber. Among these, from the viewpoint of having excellent heat resistance and film-forming properties, a phenoxy resin, a polyimide resin, an acrylic resin, an acrylic rubber, a cyanate ester resin, and a polycarbodiimide resin are preferred, and a phenoxy resin, a polyimide resin, and an acrylic resin are more preferred. These components (a) can be used singly, or can be used as a mixture or a copolymer of two or more kinds thereof.

The weight average molecular weight (Mw) of the component (a) is preferably 10000 or more, more preferably 20000, and even more preferably 25000 or more. When such a component (a) is used, the film-forming properties and the heat resistance of the adhesive can be further improved. Furthermore, when the weight average molecular weight is 10000 or more, flexibility is easily imparted to a film-shaped bonding adhesive layer, and therefore, more excellent processability is likely to be obtained. Furthermore, the weight average molecular weight of the component (a) is preferably 1000000 or less, more preferably 500000 or less, and even more preferably 100000 or less. When such a component (a) is used, since the viscosity of the film is decreased, the embeddability into bumps is improved, and mounting can be achieved with even fewer voids. From these viewpoints, the weight average molecular weight of the component (a) is preferably 10000 to 1000000, more preferably 20000 to 500000, and even more preferably 25000 to 100000.

In the present specification, the above-described weight average molecular weight indicates a weight average molecular weight measured using Gel Permeation Chromatography (GPC) and calculated relative to polystyrene standards. An example of the measurement conditions for the GPC method is shown below.

Apparatus: HCL-8320GPC, UV-8320 (product name, manufactured by Tosoh Corporation), or HPLC-8020 (product name, manufactured by Tosoh Corporation)

Column: TSKgel superMultipore HZ-M×2 or 2 pieces of GMHXL+1 piece of G-2000XL

Detector: RI or UV detector

Column temperature: 25 to 40° C.

Eluent: A solvent that dissolves a polymer component is selected. Examples of the solvent include tetrahydrofuran (THF), N,N-dimethylformamide (DMF), N,N-dimethylacetamide (DMA), N-methylpyrrolidone (NMP), and toluene. When a solvent having polarity is selected, the concentration of phosphoric acid may be adjusted to 0.05 to 0.1 mol/L (usually 0.06 mol/L), and the concentration of LiBr may be adjusted to 0.5 to 1.0 mol/L (usually 0.63 mol/L).

Flow rate: 0.30 to 1.5 mL/min

Standard substance: Polystyrene

the ratio C_{b}/Cₐ (mass ratio) of the content C_{b} of the component (b) with respect to the content Cₐ of the component (a) is preferably 0.01 or more, more preferably 0.1 or more, and even more preferably 1 or more, and preferably 5 or less, more preferably 4.5 or less, and even more preferably 4 or less. By setting the ratio Ct/Cₐ to 0.01 or more, more satisfactory curability and adhesive strength are obtained, and by setting the ratio C_{b}/Cₐ to 5 or less, more satisfactory film-forming properties are obtained. From these viewpoints, the ratio C_{b}/Cₐ is preferably 0.01 to 5, more preferably 0.1 to 4.5, and even more preferably 1 to 4.

From the viewpoint of improving the connection reliability and the like, the glass transition temperature of the component (a) is preferably −50° C. or higher, more preferably −40° C. or higher, and even more preferably −30° C. or higher, and from the viewpoint of lamination properties, the glass transition temperature is preferably 220° C. or lower, more preferably 200° C. or lower, and even more preferably 180° C. or lower. The glass transition temperature of the component (a) is preferably −50 to 220° C., more preferably −40 to 200° C., and even more preferably −30 to 180° C. When a bonding adhesive layer containing such a component (a) is used, the amount of wafer warpage can be further reduced during a wafer-level mounting process, and the heat resistance and the film-forming properties of the bonding adhesive layer can be further improved. The glass transition temperature of the component (a) can be measured using a differential scanning calorimeter (DSC).

The content of the component (a) is preferably 30% by mass or less, more preferably 25% by mass or less, and even more preferably 20% by mass or less, based on the total solid content of the bonding adhesive layer. When the content of the component (a) is 30% by mass or less, the bonding adhesive layer can obtain satisfactory reliability during a temperature cycle test, and satisfactory adhesive strength can be obtained at a reflow temperature of approximately 260° C. even after absorbing moisture. Furthermore, the content of the component (a) is preferably 1% by mass or more, more preferably 3% by mass or more, and even more preferably 5% by mass or more, based on the total solid content of the bonding adhesive layer. When the content of the component (a) is 1% by mass or more, in the bonding adhesive layer, the amount of wafer warpage can be further reduced during a wafer-level mounting process, and at the same time, the heat resistance and the film-forming properties of the bonding adhesive layer can be further improved. Furthermore, when the content of the component (a) is 5% by mass or more, the occurrence of burrs and chips during outer shaping into a wafer shape can be suppressed. From the above-described viewpoints and from the viewpoint that flexibility is easily imparted to a film-shaped bonding adhesive layer, and more excellent processability is easily obtained, the content of the component (a) is preferably 1 to 30% by mass, more preferably 3 to 30% by mass, and even more preferably 5 to 30% by mass, based on the total solid content of the bonding adhesive layer. In the present specification, the “total solid content of the bonding adhesive layer” may be rephrased into “total amount of components (a) to (e)”.

### (b) Thermosetting Resin

As the component (b), a resin having two or more reactive groups in the molecule can be used without any particular limitation. When the bonding adhesive layer contains a thermosetting resin, the adhesive can be cured by heating, and the cured adhesive exhibits high heat resistance and adhesive strength to a chip and obtains excellent reflow resistance.

Examples of the component (b) include an epoxy resin, a phenol resin, an imide resin, a urea resin, a melamine resin, a silicon resin, a (meth)acrylic compound, and a vinyl compound. Among these, from the viewpoint of having excellent heat resistance (reflow resistance) and storage stability, an epoxy resin, a phenol resin, and an imide resin are preferred, an epoxy resin and an imide resin are more preferred, and an epoxy resin is even more preferred. These components (b) can be used singly, or can be used as a mixture or a copolymer of two or more kinds thereof.

Regarding the epoxy resin and the imide resin, for example, a bisphenol A type epoxy resin, a bisphenol F type epoxy resin, a naphthalene type epoxy resin, a phenol novolac type epoxy resin, a cresol novolac type epoxy resin, a phenol aralkyl type epoxy resin, a biphenyl type epoxy resin, a triphenylmethane type epoxy resin, a dicyclopentadiene type epoxy resin, and various polyfunctional epoxy resins; and a nadimide resin, an allylnadimide resin, a maleimide resin, an amideimide resin, an imide acrylate resin, various polyfunctional imide resins, and various polyimide resins can be used. These can be used singly or as mixtures of two or more kinds thereof.

From the viewpoint of suppressing decomposition and generation of volatile components at the time of connection at high temperatures, when the temperature at the time of connection is 250° C., it is preferable to use a component (b) having a thermal weight loss rate at 250° C. of 5% or less, and when the temperature at the time of connection is 300° C., it is preferable to use a thermal weight loss rate at 300° C. of 5% or less.

The content of the component (b) is, for example, 5% by mass or more, preferably 15% by mass or more, and more preferably 30% by mass or more, based on the total solid content of the bonding adhesive layer. The content of the component (b) is, for example, 80% by mass or less, preferably 70% by mass or less, and more preferably 60% by mass or less, based on the total solid content of the bonding adhesive layer. The content of the component (b) is, for example, 5 to 80% by mass, preferably 15 to 70% by mass, and more preferably 30 to 60% by mass, based on the total solid content of the bonding adhesive layer.

### (c) Curing Agent

The component (c) may be a curing agent capable of forming a salt with a flux compound that will be described below. Examples of the component (c) include an amine-based curing agent (an amine) and an imidazole-based curing agent (an imidazole). When the component (c) includes an amine-based curing agent or an imidazole-based curing agent, the component (c) exhibits flux activity of suppressing the generation of an oxide film at the connecting parts, and can improve connection reliability and insulation reliability. Furthermore, when the component (c) includes an amine-based curing agent or an imidazole-based curing agent, storage stability is further improved, and there is a tendency that decomposition or deterioration due to moisture absorption is less likely to occur. In addition, when the component (c) includes an amine-based curing agent or an imidazole-based curing agent, the curing rate can be easily adjusted, and short-time connection intended for improving productivity can be easily realized due to rapid curability.

Each of the curing agents will be described below.

### (i) Amine-Based Curing Agent

As the amine-based curing agent, for example, dicyandiamide can be used.

The content of the amine-based curing agent is preferably 0.1 parts by mass or more, preferably 10 parts by mass or less, and more preferably 5 parts by mass or less, with respect to 100 parts by mass of the above-described component (b). When the content of the amine-based curing agent is 0.1 parts by mass or more, curability tends to improve, and when the content is 10 parts by mass or less, the bonding adhesive layer is not cured before a metal joint is formed, and there is a tendency that connection failure is less likely to occur. From these viewpoints, the content of the amine-based curing agent is preferably 0.1 to 10 parts by mass, and more preferably 0.1 to 5 parts by mass, with respect to 100 parts by mass of the component (b).

### (ii) Imidazole-Based Curing Agent

Examples of the imidazole-based curing agent include 2-phenylimidazole, 2-phenyl-4-methylimidazole, 1-benzyl-2-methylimidazole, 1-benzyl-2-phenylimidazole, 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adduct, 2-phenylimiazole isocyanuric acid adduct, 2-phenyl-4,5-dihydroxymethylimidazole, 2-phenyl-4-methyl-5-hydroxymethylimidazole, and an adduct of an epoxy resin and an imidazole. Among these, from the viewpoints of excellent curability, storage stability, and connection reliability, 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-ethyl-4′-methylimidazolyl-(1′)]-ethyl-s-triazine, 2-phenylimidazole isocyanuric acid adduct, 2-phenyl-4,5-dihydroxymethylimidazole, and 2-phenyl-4-methyl-5-hydroxymethylimidazole are preferred. Furthermore, from the viewpoint of more sufficiently obtaining the effects of the present disclosure, 2-phenyl-4,5-dihydroxymethylimidazole is preferred. These can be used singly or in combination of two or more kinds thereof. Furthermore, latent curing agents obtained by microencapsulating these curing agents can also be used.

The content of the imidazole-based curing agent is preferably 0.1 parts by mass or more, and is preferably 10 parts by mass or less, and more preferably 5 parts by mass or less, with respect to 100 parts by mass of the component (b). When the content of the imidazole-based curing agent is 0.1 parts by mass or more, curability tends to improve. When the content of the imidazole-based curing agent is 10 parts by mass or less, the bonding adhesive layer does not cure before a metal joint is formed, connection failure is less likely to occur, and the occurrence of voids in the curing process in a pressurized atmosphere is easily suppressed. From these viewpoints, the content of the imidazole-based curing agent is preferably 0.1 to 10 parts by mass, and more preferably 0.1 to 5 parts by mass, with respect to 100 parts by mass of the component (b).

The component (c) can be used singly or as a mixture of two or more kinds thereof. For example, the imidazole-based curing agent may be used alone, or may be used together with an amine-based curing agent. As the component (c), a curing agent other than those mentioned above that function as curing agents for the component (b), can also be used.

The content of the component (c) is preferably 0.2 parts by mass or more, and more preferably 0.5 parts by mass or more, and is preferably 20 parts by mass or less, more preferably 6 parts by mass or less, and even more preferably 5 parts by mass or less, with respect to 100 parts by mass of the component (b). When the content of the component (c) is 0.2 parts by mass or more, sufficient curing tends to proceed. When the content of the component (c) is 20 parts by mass or less, curing proceeds rapidly, thereby suppressing an increase in the number of reaction points, there is a tendency that decrease in reliability due to shortening of the molecular chain or remaining of unreacted groups can be prevented, and in addition, remaining of voids during curing in a pressurized atmosphere is easily suppressed. From these viewpoints, the content of the component (c) is preferably 0.2 to 20 parts by mass, more preferably 0.5 to 6 parts by mass, and even more preferably 0.5 to 5 parts by mass, with respect to 100 parts by mass of the component (b).

The content of the component (c) is preferably 0.5% by mass or more and is preferably 2.3% by mass or more, and more preferably 2.0% by mass or less, based on the total solid content of the bonding adhesive layer. When the content of the component (c) is 0.5% by mass or more, sufficient curing tends to proceed. When the content of the component (c) is 2.3% by mass or less, curing rapidly proceeds, thereby suppressing an increase in the number of reaction points, there is a tendency that decrease in reliability due to shortening of the molecular chain or remaining of unreacted groups can be prevented, and in addition, remaining of voids during curing in a pressurized atmosphere is easily suppressed. From these viewpoints, the content of the component (c) is preferably 0.5 to 2.3% by mass, and more preferably 0.5 to 2.0% by mass, based on the total solid content of the bonding adhesive layer.

### (d) Flux Compound

The component (d) is a compound having flux activity (flux agent). When the bonding adhesive layer contains the component (d), an oxide film of metal of the connecting parts and the coating obtained by an OSP treatment can be removed, and therefore, excellent connection reliability is likely to be obtained.

The component (d) includes at least one selected from the group consisting of a compound having an aromatic ring, a compound having an aliphatic ring, and a compound having a number of main chain (portion excluding carboxyl groups)-constituting atoms of 4, 6, or 8 or more. When the component (d) includes the above-described specific compound, even when the laminated film is used after being left to stand in a room temperature environment for a long period of time, deterioration in the wettability of solder to the metal of the connecting part can be suppressed. This is because regarding the above-described specific compound, movement thereof within the bonding adhesive layer is likely to be suppressed, and movement thereof to migrate from the bonding adhesive layer to the adhesive layer is suppressed. As the component (d) stays within the bonding adhesive layer without migrating from the bonding adhesive layer to the adhesive layer, when the connecting part of the semiconductor chip and the connecting part of a wiring circuit board, a semiconductor wafer, or another semiconductor chip are connected, the flux activity of the bonding adhesive layer is sufficiently exhibited, and decrease in the wettability of solder to the metal of the connecting parts can be suppressed.

Here, it is speculated that the compound having an aromatic ring, the compound having an aliphatic ring, and the compound having a number of main chain-constituting atoms of 4, 6, or 8 or more are less likely to migrate from the bonding adhesive layer to the adhesive layer due to the molecular structures thereof. A compound having an aromatic ring and a compound having an aliphatic ring are bulky because they both have a ring structure, and compounds having a bulky structure are less likely to move within the bonding adhesive layer and are consequently less likely to migrate to the adhesive layer. Furthermore, a compound having a number of main chain-constituting atoms of 8 or more is also less likely to move within the bonding adhesive layer because the compound has a long main chain, and as a result, the compound is less likely to migrate to the adhesive layer. Meanwhile, the reason why a compound having a number of main chain-constituting atoms of 4 or 6 is less likely to migrate from the bonding adhesive layer to the adhesive layer is as follows.

That is, the present inventors found that a compound having an even number of main chain-constituting atoms is suppressed from moving within the bonding adhesive layer and is less likely to migrate to the adhesive layer, as compared with a compound having an odd number of main chain-constituting atoms. This is speculated to be because a compound having an even number of main chain-constituting atoms is likely to form a cyclic dimer. When the number of main chain-constituting atoms is an even number, as will be shown in the following formula (I), in the two compounds (the following formula (I) shows the case of adipic acid having a number of main chain constituting atoms of 4), hydrogen bonding is formed each between a carbonyl group of one compound and a hydroxy group of the other compound and between a hydroxyl group of one compound and a carbonyl group of the other compound, and a cyclic dimer is likely to be formed. Since a cyclic dimer has a steric structure, it is less likely to pass through a polymer network of the compound (a) in the bonding adhesive layer, as compared with a monomer and a chain-shaped dimer having planar structures. Furthermore, while a chain-shaped dimer is bonded at one end, a cyclic dimer is bonded at both ends, and therefore, the cyclic dimer is less likely to dissociate and is likely to stably exist in a dimer state. Therefore, it is believed that a compound having an even number of main chain-constituting atoms is suppressed from moving within the bonding adhesive layer and is less likely to migrate to the adhesive layer. Incidentally, when the number of main chain-constituting atoms is an odd number, as shown in the following formula (II), in the two compounds (the following formula (II) shows the case of glutaric acid having a number of main chain-constituting atoms of 3), since a carbonyl group of one compound and a hydroxy group of the other compound are separated apart from each other, a cyclic dimer is less likely to be formed, and in a case where a dimer is formed, a chain-shaped dimer is likely to be formed as shown in the following formula (III). Therefore, a compound having an odd number of main chain-constituting atoms is believed to exist in the form of a monomer or a chain-shaped dimer within the bonding adhesive layer.

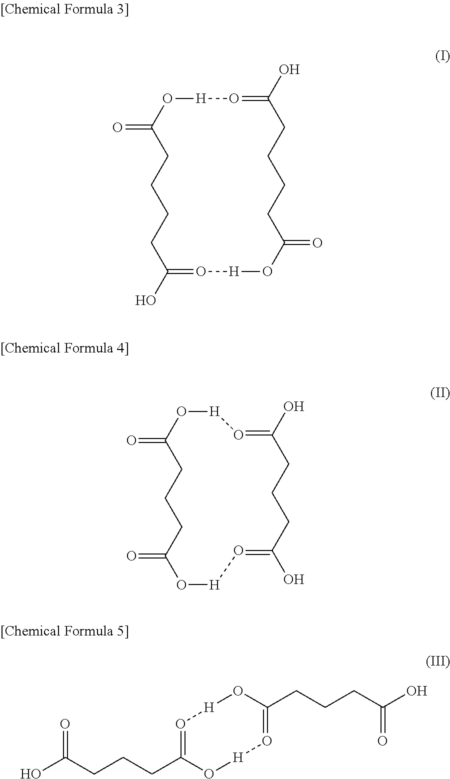

FT-IR measurement of glutaric acid (number of main chain-constituting atoms: 3) and adipic acid (number of main chain-constituting atoms: 4) was performed, and the state of existence of these compounds was checked. The measurement conditions were as follows, and the state of existence of the compounds was checked by comparing the FT-IR spectra based on actual measurement and calculation.

(Actual measurement)

A film-shaped bonding adhesive layer was cut into a size of 1.0 cm×1.0 cm to be used as a sample, and the FT-IR spectrum of this sample surface was measured using an ALPHA Compact Infrared Spectrometer (manufactured by Bruker Optics, ATR method). Here, as the film-shaped bonding adhesive layer, the bonding adhesive layer of Comparative Example 1 that will be described below was used in the case of glutaric acid, and the bonding adhesive layer of Example 1 that will be described below was used in the case of adipic acid.

### (Calculation)

The structure of a target flux compound was drawn using molecular structure modeling software: “Chem3D”, and an input file was created using the drawn structure and using input file creation software for modeling and calculation of molecular structures: “Avogadro”. Structure optimization and oscillation frequency calculation were executed using quantum chemical calculation software (semi-empirical technique, PM3): “Firefly”. From the results of oscillation frequency calculation, the IR spectrum was outputted using quantum chemical calculation GUI software: “MoCalc2012”.

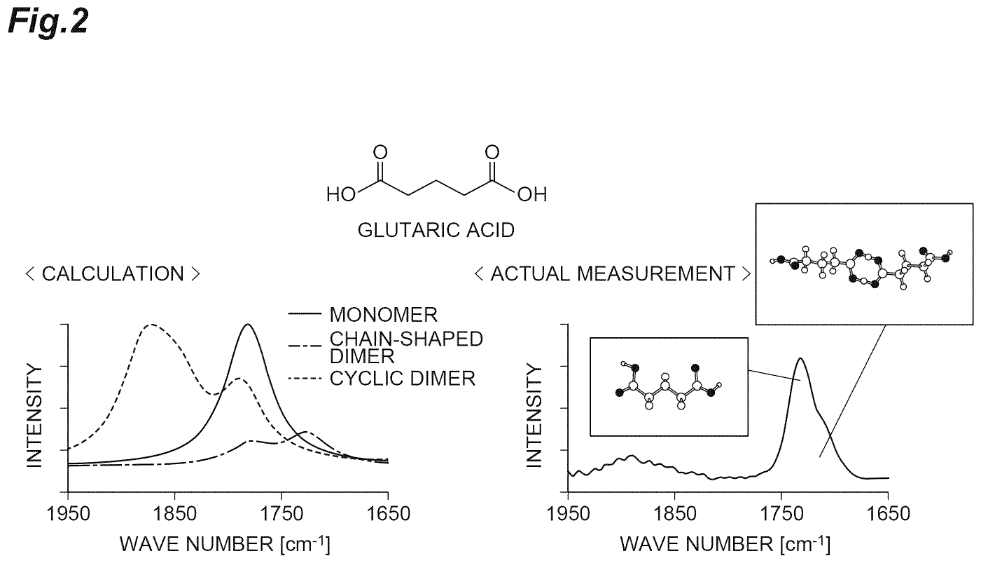

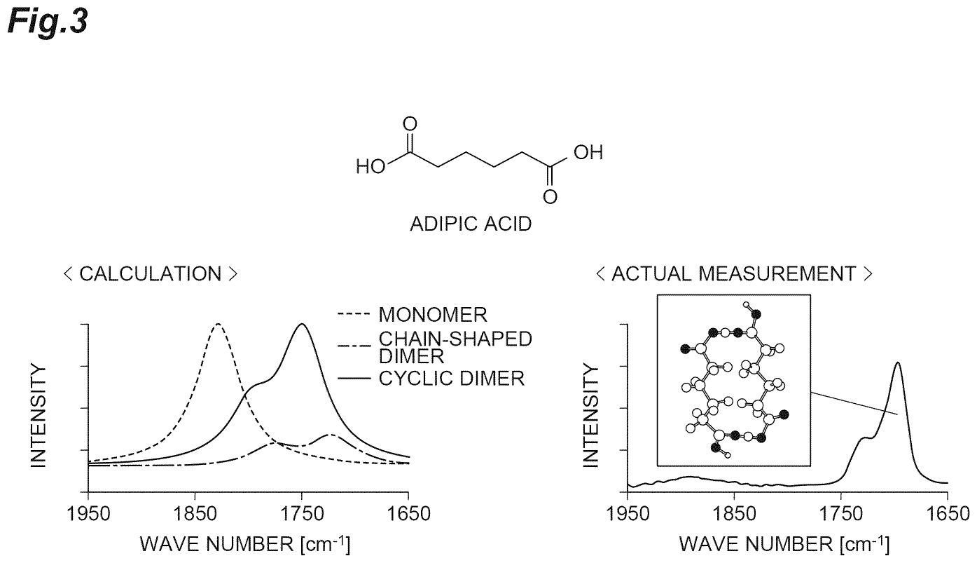

FIG. 2 is FT-IR spectra (calculation and actual measurement) of glutaric acid. From the results shown in FIG. 2, it was verified that glutaric acid mainly exists in the state of a monomer or a chain-shaped dimer. FIG. 3 is FT-IR spectra (calculation and actual measurement) of adipic acid. From the results shown in FIG. 3, it was verified that adipic acid mainly exists in the state of a cyclic dimer. Incidentally, FT-IR measurement was also performed for pimelic acid (number of main chain-constituting atoms: 5), suberic acid (number of main chain-constituting atoms: 6), azelaic acid (number of main chain-constituting atoms: 7), and sebacic acid (number of main chain-constituting atoms: 8), and it was verified that compounds having an odd number of main chain-constituting atoms mainly exist in the state of a monomer or a chain-shaped dimer as is the case of glutaric acid, while it was verified that compounds having an even number of main chain-constituting atoms mainly exist in the state of a cyclic dimer as is the case of adipic acid.

Examples of the compound having a number of main chain-constituting atoms of 4, 6, or 8 or more include adipic acid, suberic acid, sebacic acid, thapsic acid, dithiodiglycolic acid, 3,3′-dithiodipropionic acid, and 4,4′-dithiodipropionic acid. These can be used singly or in combination of two or more kinds thereof. Among these, from the viewpoint that decrease in the wettability of solder to the metal of the connecting part can be suppressed more sufficiently even in a case where the laminated film is used after being left to stand in a room temperature environment for a long period of time, adipic acid, suberic acid, sebacic acid, and thapsic acid are preferred. The compound having a number of main chain-constituting atoms of 4, 6, or 8 or more is a compound that contains none of an aromatic ring and an aliphatic ring. Compounds containing at least one of an aromatic ring and an aliphatic ring are classified as compounds having an aromatic ring or compounds having an aliphatic ring.

The number of main chain-constituting atoms in the compound having a number of main chain-constituting atoms of 4, 6, or 8 or more may be 4, 6, or 8 to 14, or may be 4, 6, or 8, from the viewpoint that decrease in the wettability of solder to the metal of the connecting part can be suppressed more sufficiently even in a case where the laminated film is used after being left to stand in a room temperature environment for a long period of time.

Examples of the main chain-constituting atom in the compound having a number of main chain-constituting atoms of 4, 6, or 8 or more include a carbon atom, a sulfur atom, and an oxygen atom, and the main chain-constituting atom may be a carbon atom or a sulfur atom, or may be a carbon atom.

The compound having a number of main chain-constituting atoms of 4, 6, or 8 or more may include a compound represented by the following general formula (1), or may contain a compound represented by the following general formula (2), from the viewpoint that decrease in the wettability of solder to the metal of the connecting part can be suppressed more sufficiently even in a case where the laminated film is used after being left to stand in a room temperature environment for a long period of time.

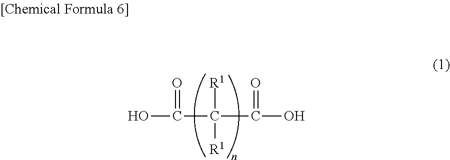

In formula (1), R¹ represents a hydrogen atom or a monovalent organic group; and n represents an integer of 4, 6, or 8 to 14. Incidentally, a plurality of R¹'s existing therein may be identical with or different from each other.

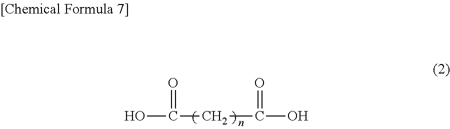

In formula (2), n represents an integer of 4, 6, or 8 to 14.

Examples of the compound having an aromatic ring include phthalic acid, isophthalic acid, and terephthalic acid. These can be used singly or in combination of two or more kinds thereof. Among these, from the viewpoint that decrease in the wettability of solder to the metal of the connecting part can be suppressed more sufficiently even in a case where the laminated film is used after being left to stand in a room temperature environment for a long period of time, phthalic acid and isophthalic acid are preferred.

Examples of the compound having an aliphatic ring include 1,3-cyclohexanedicarboxylic acid and 1,4-cyclohexanedicarboxylic acid. These can be used singly or in combination of two or more kinds thereof. Among these, from the viewpoint that decrease in the wettability of solder to the metal of the connecting part can be suppressed more sufficiently even in a case where the laminated film is used after being left to stand in a room temperature environment for a long period of time, 1,3-cyclohexanedicarboxylic acid and 1,4-cyclohexanedicarboxylic acid are preferred.

The melting point of the component (d) is preferably 50° C. or higher, more preferably 60° C. or higher, even more preferably 70° C. or higher, and particularly preferably 100° C. or higher, and is preferably 200° C. or lower, more preferably 180° C. or lower, and even more preferably 160° C. or lower. When the melting point of the component (d) is 200° C. or lower, flux activity is likely to be exhibited sufficiently before a curing reaction between the thermosetting resin and the curing agent occurs. Therefore, when a bonding adhesive layer containing such a component (d) is used, the component (d) melts at the time of mounting a chip, an oxide film on the solder surface is removed, and thereby a semiconductor device having more excellent connection reliability can be realized. Furthermore, when the melting point of the component (d) is 50° C. or higher, a reaction at room temperature or on a high-temperature stage is less likely to begin, and more excellent storage stability is obtained. From these viewpoints, the melting point of the component (d) is preferably 50 to 200° C., more preferably 60 to 200° C., even more preferably 70 to 180° C., and particularly preferably 100 to 160° C. Particularly, when the melting point of the component (d) is 100 to 160° C., even in a case where the laminated film is used after being left to stand in a room temperature environment for a long period of time, decrease in the wettability of solder to the metal of the connecting part can be suppressed more sufficiently.

The melting point of the component (d) can be measured using a common melting point measuring device. A sample for measuring the melting point is required to be pulverized into a fine powder, and a small amount thereof is required to be used, so as to reduce the temperature deviation within the sample. As a container for the sample, a capillary tube with one end closed is often used; however, depending on the measuring device, the sample may be sandwiched between two sheets of microscope cover glasses as the container. Furthermore, when the temperature is rapidly increased, a temperature gradient is generated between the sample and the thermometer, resulting in measurement errors, and therefore, it is desirable to measure heating at the time point of measuring the melting point, at an increase rate of 1° C. or less every minute.

Since the sample is prepared as a fine powder as described above, the sample before melting is opaque due to diffuse reflection at the surface. The temperature at which the sample begins to become transparent in appearance is usually regarded as the lower limit point of the melting point, and the temperature at which the sample has completely melted is usually regarded as the upper limit point. There are various forms of measuring device; however, the most classic device used is a device in which a capillary tube filled with a sample is attached to a double tube type thermometer and is heated in a warm bath. For the purpose of attaching a capillary tube to the double tube type thermometer, a highly viscous liquid is used as the liquid of the warm bath, concentrated sulfuric acid or silicone oil is often used, and the capillary tube is attached such that the sample comes to the vicinity of the reservoir at the tip of the thermometer. Furthermore, as the melting point measuring device, one that uses a metal heat block for heating and automatically determines the melting point while adjusting the heating while measuring the light transmittance, can also be used.

In the present specification, the melting point being 200° C. or lower means that the upper limit point of the melting point is 200° C. or lower, and the melting point being 50° C. or higher means that the lower limit point of the melting point is 50° C. or higher.

The acid dissociation constant pKa of the component (d) may be 5.0 or less or 4.6 or less. Furthermore, the acid dissociation constant pKa of the component (d) may be 2.0 or more, 2.5 or more, or 3.5 or more. When the acid dissociation constant pKa of the component (d) is 5.0 or less, the laminated film can have sufficient flux activity, and when the acid dissociation constant is 2.0 or more, the post-thermal history reaction rate due to the thermal history at the time of temporary fixing can be reduced.

The content of the component (d) is preferably 0.1% by mass or more, more preferably 0.5% by mass or more, and even more preferably 1% by mass or more, and is preferably 10% by mass or less, more preferably 5% by mass or less, and even more preferably 3% by mass or less, based on the total solid content of the bonding adhesive layer. From the viewpoints of connection reliability and reflow resistance during the production of a semiconductor device, and from the viewpoint that decrease in the wettability of solder to the metal of the connecting part can be suppressed more sufficiently even when the laminated film is used after being left to stand in a room temperature environment for a long period of time, the content of the component (d) is preferably 0.1 to 10% by mass, more preferably 0.5 to 5% by mass, and even more preferably 1 to 3% by mass, based on the total solid content of the bonding adhesive layer. When the flux compound corresponds to any of the components (a) to (e), the content of the component (d) is calculated by assuming that the flux compound also corresponds to the component (d).

In the present embodiment, the equivalent ratio (carboxyl group/basic functional group, molar ratio) of carboxyl groups (acidic functional groups) in the total amount of the component (d) with respect to basic functional groups in the total amount of the component (c) is preferably 1.0 or more, and is preferably 3.0 or less. The above-described equivalent ratio is more preferably 1.3 or more, and even more preferably 1.5 or more, and is more preferably 2.5 or less, and even more preferably 2.0 or less.

### (e) Filler

The bonding adhesive layer may contain a filler (component (e)) as necessary. By containing the component (e), the viscosity of the bonding adhesive layer, the physical properties of a cured product of the bonding adhesive layer, and the like can be controlled. Specifically, when the component (e) is used, for example, suppression of void occurrence at the time of connection, reduction of the moisture absorption rate of a cured product of the bonding adhesive layer, and the like can be promoted.

As the component (e), an insulating inorganic filler, whiskers, a resin filler, and the like can be used. Furthermore, as the component (e), one kind thereof may be used alone, or two or more kinds thereof may be used in combination.

Examples of the insulating inorganic filler include glass, silica, alumina, titanium oxide, carbon black, mica, and boron nitride. Among these, silica, alumina, titanium oxide, and boron nitride are preferred, and silica, alumina, and boron nitride are more preferred.

Examples of the whiskers include aluminum borate, aluminum titanate, zinc oxide, calcium silicate, magnesium sulfate, and boron nitride.

Examples of the resin filler include fillers made of resins such as polyurethane and polyimide.

A resin filler has a small coefficient of thermal expansion as compared with organic components (an epoxy resin, a curing agent, and the like), and therefore has an excellent effect of improving connection reliability. Furthermore, when a resin filler is used, adjustment of the viscosity of the bonding adhesive layer can be easily carried out. Furthermore, a resin filler has an excellent function of relaxing stress as compared with an inorganic filler.

An inorganic filler has a small coefficient of thermal expansion as compared with a resin filler, and therefore, a decrease in the coefficient of thermal expansion of the bonding adhesive layer can be realized when an inorganic filler is used. Furthermore, since many inorganic fillers are general-purpose products with controlled particle sizes, they are also preferable for viscosity adjustment.

Since a resin filler and an inorganic filler each have advantageous effects, either one may be used depending on the use application, or a mixture of the two may be used in order to exhibit the functions of both.

The shape, particle size, and content of the component (e) are not particularly limited. Furthermore, the component (e) may be a material with its physical properties appropriately adjusted by a surface treatment.

The content of the component (e) is preferably 10% by mass or more, and more preferably 15% by mass or more, and is preferably 80% by mass or less, and more preferably 60% by mass or less, based on the total solid content of the bonding adhesive layer. The content of the component (e) is preferably 10 to 80% by mass, and more preferably 15 to 60% by mass, based on the total solid content of the bonding adhesive layer.

It is preferable that the component (e) is composed of an insulating material. When the component (e) is composed of a conductive material (for example, solder, gold, silver, or copper), there is a risk that insulation reliability (particularly, HAST resistance) may decrease.

### (Other Components)

In the bonding adhesive layer, additives such as an oxidation inhibitor, a silane coupling agent, a titanium coupling agent, a leveling agent, and an ion trapping agent may be blended. These can be used singly or in combination of two or more kinds thereof. The blending amounts thereof may be appropriately adjusted so that the effect of each additive is exhibited.

An example of a method for producing a bonding adhesive layer (film-shaped adhesive) will be shown below. First, the component (a), component (b), component (c), and component (d), and the component (e) and the like that are added as needed, are added into an organic solvent, and the mixture is dissolved or dispersed by stirring, mixing, kneading, or the like to prepare a resin varnish. Thereafter, the resin varnish is applied on a base material film that has been subjected to a release treatment, using a knife coater, a roll coater, an applicator, or the like, subsequently the organic solvent is removed by heating, and thereby a bonding adhesive layer (film-shaped adhesive) can be formed on the base material film.

The thickness of the bonding adhesive layer is not particularly limited; however, for example, the thickness is preferably 0.5 to 1.5 times, more preferably 0.6 to 1.3 times, and even more preferably 0.7 to 1.2 times, the height of the bumps before connection.

When the thickness of the bonding adhesive layer is 0.5 or more times the height of the bumps, the occurrence of voids due to non-filling of the adhesive can be sufficiently suppressed, and connection reliability can be further improved. Furthermore, when the thickness is 1.5 times or less, since the amount of the adhesive pushed out from the chip connecting region at the time of connection can be sufficiently suppressed, the adhesion of the adhesive to unnecessary parts can be sufficiently prevented. When the thickness of the adhesive is larger than 1.5 times, the bumps have to remove a large amount of adhesive, and conduction failure is likely to occur. Furthermore, with regard to weakening of bumps (miniaturization of bump diameter) due to narrower pitch and an increase in the pin number, it is not preferable to remove a large amount of resin because the damage to the bumps increases.

Generally, when the height of the bumps is 5 to 100 μm, the thickness of the bonding adhesive layer is preferably 2.5 to 150 μm, and more preferably 3.5 to 120 μm.

It is preferable that the organic solvent to be used for preparing the resin varnish has characteristics capable of uniformly dissolving or dispersing each component, and examples thereof include dimethylformamide, dimethylacetamide, N-methyl-2-pyrrolidone, dimethyl sulfoxide, diethylene glycol dimethyl ether, toluene, benzene, xylene, methyl ethyl ketone, tetrahydrofuran, ethyl cellosolve, ethyl cellosolve acetate, butyl cellosolve, dioxane, cyclohexanone, and ethyl acetate. These organic solvents can be used singly or in combination of two or more kinds thereof. Stirring, mixing, and kneading at the time of preparing the resin varnish can be carried out using, for example, a stirrer, a mortar machine, a three-roll mill, a ball mill, a bead mill, or a homo-disper.

The base material film is not particularly limited as long as it has heat resistance that can withstand the heating conditions when volatilizing the organic solvent, and examples thereof include polyolefin films such as a polypropylene film and a polymethylpentene film; polyester films such as a polyethylene terephthalate film and a polyethylene naphthalate film; a polyimide film, and a polyetherimide film. The base material film is not limited to a single layer film formed from these films, and may be a multilayer film made of two or more kinds of materials.

It is preferable that the drying conditions at the time of volatilizing the organic solvent from the resin varnish applied on the base material film are set to conditions in which the organic solvent is sufficiently volatilized, and specifically, it is preferable that heating is performed at 50 to 200° C. for 0.1 to 90 minutes. It is preferable that the organic solvent is removed up to 1.5% by mass or less with respect to the total amount of the bonding adhesive layer.

From the viewpoint that voids are more easily removed at the time of curing in a pressurized atmosphere, and even more excellent reflow resistance is obtained, the lowest melt viscosity of the bonding adhesive layer is preferably 200 to 10000 Pas, and more preferably 200 to 5000 Pa·s. The lowest melt viscosity can be measured using a melt viscosity measuring device under the conditions of a measurement temperature of 0 to 200° C., a temperature increase rate of 10° C./min, a frequency of 10 Hz, and a strain of 1%. The temperature at which the bonding adhesive layer exhibits the lowest melt viscosity (melting temperature) is preferably 100 to 250° C., more preferably 120 to 230° C., and even more preferably 140 to 200.

From the viewpoint that temporary fixing of the semiconductor chip is facilitated in a temperature region of 60 to 170° C., the bonding adhesive layer preferably has a melt viscosity at 80° C. of 2000 to 30000 Pa-s, preferably has a melt viscosity at 130° C. of 400 to 20000 Pa·s, and more preferably has a melt viscosity at 80° C. of 4000 to 20000 Pas and a melt viscosity at 130° C. of 400 to 5000 Pa·s. The above-described melt viscosity can be measured by the above-mentioned method using a melt viscosity measuring device.

### (Back Grinding Tape 4)

The back grinding tape may include one or more adhesive layers and one or more base material layers, or may be composed of one adhesive layer and one base material layer. The laminated film of the present embodiment can be used for both use applications of back grinding and circuit member connection. In that case, the bonding adhesive layer is stuck to the principal surface of the semiconductor wafer on which electrodes are provided.

It is preferable that the adhesive layer has tacky adhesive strength at room temperature and has the necessary close adhesive strength to the adherend. Furthermore, it is preferable that the adhesive layer has characteristics of being cured (tacky adhesive strength is decreased) by high energy rays such as radiation or heat; however, it is more preferable that the adhesive layer can be easily peeled from the bonding adhesive layer even without applying high-energy rays such as radiation or heat. Furthermore, the adhesive layer may be a pressure-sensitive type adhesive layer. The adhesive layer can be formed using, for example, an acrylic resin, various synthetic rubbers, natural rubber, or a polyimide resin.

The thickness of the adhesive layer may be 5 to 100 μm, or may be 10 to 80 μm.

Examples of the base material layer include plastic films such as a polyester film, a polytetrafluoroethylene film, a polyethylene film, a polypropylene film, and a polymethylpentene film. Among these, a polyester film is preferred, and a polyethylene terephthalate film is more preferred. Furthermore, the base material layer may be a mixture of two or more kinds selected from the above-described materials, or a multilayered structure of the above-described films.

The thickness of the base material layer may be 10 to 100 μm, or may be 20 to 80 μm.

The thickness of the back grinding tape may be 10 to 200 μm, or may be 20 to 150 μm.

### <Semiconductor Device>

A semiconductor device produced using the laminated film according to the present embodiment will be described. The semiconductor device according to the present embodiment is a semiconductor device in which connecting parts of a semiconductor chip and a wiring circuit board are electrically connected to each other, or a semiconductor device in which connecting parts of a plurality of semiconductor chips are electrically connected to each other. For the semiconductor device according to the present embodiment, for example, flip-chip connection by which electrical connection is obtained by utilizing a bonding adhesive layer can be used.

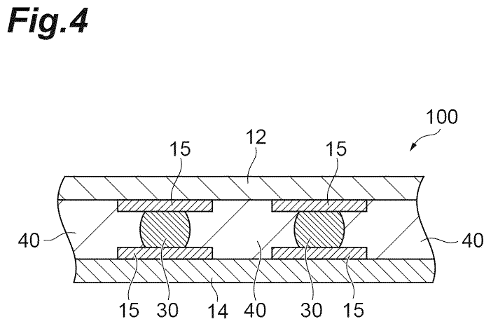

FIG. 4 is a schematic cross-sectional view illustrating an embodiment of a semiconductor device (COB-type connection mode of a semiconductor chip and a substrate). As shown in FIG. 4, the semiconductor device 100 has: a semiconductor chip 12 and a substrate (wiring circuit board) 14 facing each other; wiring lines 15 arranged on each of mutually facing surfaces of the semiconductor chip 12 and the substrate 14; connecting bumps 30 connecting the wiring lines 15 of the semiconductor chip 12 and the substrate 14 to each other; and a bonding adhesive layer 40 filling voids between the semiconductor chip 12 and the substrate 14 without any gap. The semiconductor chip 12 and the substrate 14 are flip-chip connected by the wiring lines 15 and the connecting bumps 30. The wiring lines 15 and the connecting bumps 30 are sealed by the bonding adhesive layer 40 and isolated from the external environment.

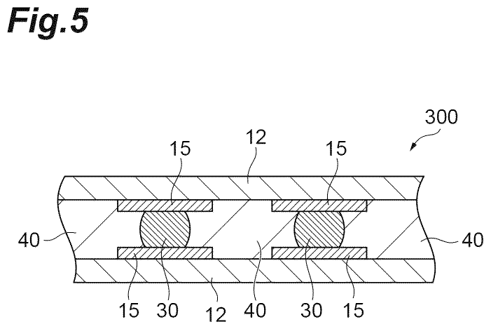

FIG. 5 is a schematic cross-sectional view illustrating another embodiment of the semiconductor device (COC-type connection mode between semiconductor chips). As shown in FIG. 5, the semiconductor device 300 is the same as the semiconductor device 100, except that two semiconductor chips 12 are flip-chip connected by wiring lines 15 and connecting bumps 30.

The semiconductor chip 12 is not particularly limited, and various semiconductors such as elemental semiconductors composed of the same type of element such as silicon and germanium, and compound semiconductors such as gallium arsenide and indium phosphide, can be used.

The substrate 14 is not particularly limited as long as it is a wiring circuit board, and a circuit substrate in which wiring lines (wiring pattern) are formed by etching away unnecessary parts of a metal layer formed on the surface of an insulating substrate containing glass epoxy, polyimide, polyester, ceramic, epoxy, bismaleimide triazine, polyimide, or the like as a main component; a circuit substrate in which wiring lines (wiring pattern) are formed on the surface of the above-described insulating substrate by metal plating or the like; a circuit substrate in which wiring lines (wiring pattern) are formed on the surface of the above-described insulating substrate by printing a conductive substance; and the like can be used.

The connecting part of the wiring lines 15 and the like contains gold, silver, copper, solder (main components are, for example, tin-silver, tin-lead, tin-bismuth, or tin-copper), nickel, tin, lead, and the like as main components, or may contain a plurality of metals.

On the surface of the wiring lines (wiring pattern), a metal layer containing gold, silver, copper, solder (main components are, for example, tin-silver, tin-lead, tin-bismuth, or tin-copper), tin, nickel, and the like as main components may be formed. This metal layer may be composed only of a single component, or may be composed of a plurality of components. Furthermore, the metal layer may have a structure in which a plurality of metal layers are laminated. Copper and solder are preferable because they are generally used for being inexpensive; however, since the substances have oxides or impurities, flux activity is required.

Furthermore, the semiconductor devices (packages) shown in FIG. 4 or FIG. 5 may be stacked and electrically connected using gold, silver, copper, solder (main components are, for example, tin-silver, tin-lead, tin-bismuth, or tin-copper), tin, nickel, or the like. Copper and solder are preferable because they are generally used for being inexpensive; however, since the substances have oxides or impurities, flux activity is required. For example, as seen in the TSV technology, semiconductor chips may be flip-chip connected or stacked, with a bonding adhesive layer interposed therebetween, and holes penetrating through the semiconductor chips may be formed and connected to electrodes on the patterned surface.

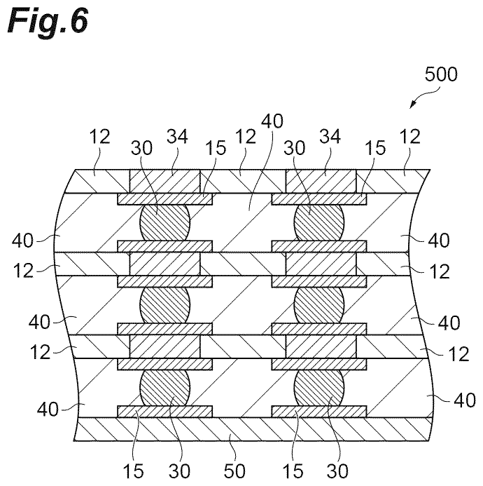

FIG. 6 is a schematic cross-sectional view illustrating another embodiment of the semiconductor device (stacked semiconductor chip-type embodiment (TSV)). In the semiconductor device 500 shown in FIG. 6, a semiconductor chip 12 and an interposer 50 are flip-chip connected as wiring lines 15 formed on the interposer 50 are connected to wiring lines 15 of the semiconductor chip 12 through connecting bumps 30. Voids between the semiconductor chip 12 and the interposer 50 are filled with a bonding adhesive layer 40 without any gap. On the surface of the above-described semiconductor chip 12 on the opposite side from the interposer 50, semiconductor chips 12 are repeatedly stacked, with wiring lines 15, connecting bumps 30, and a bonding adhesive layer 40 interposed therebetween. The wiring lines 15 on the patterned surfaces on the front and back of the semiconductor chips 12 are connected to each other by through electrodes 34 that fill the holes penetrating through the inside of the semiconductor chips 12. Incidentally, as the material for the through electrodes 34, copper, aluminum, and the like can be used.

Through such a TSV technology, signals can be acquired even from the back side of a semiconductor chip that is normally not used. In addition, since the through electrodes 34 penetrate vertically through the semiconductor chips 12, the distance between semiconductor chips 12 facing each other or between a semiconductor chip 12 and an interposer 50 can be shortened, and flexible connection is enabled. The bonding adhesive layer of the laminated film according to the present embodiment can be applied as a sealing material between semiconductor chips 12 facing each other or between a semiconductor chip 12 and an interposer 50, in such a TSV technology.

Furthermore, in a bump forming method with a high degree of freedom, such as an area bump chip technology, semiconductor chips can be directly mounted as they are on a motherboard without using interposers. The bonding adhesive layer of the laminated film according to the present embodiment can be applied even in a case where such semiconductor chips are mounted directly on a motherboard. The bonding adhesive layer of the laminated film according to the present embodiment can also be applied when sealing voids between substrates in a case where two wiring circuit boards are stacked.

### <Method for Producing Semiconductor Device>

The method for producing a semiconductor device according to an embodiment includes: a step of sticking a surface on a bonding adhesive layer side of a laminated film and a semiconductor wafer together (lamination step); a step of back grinding the semiconductor wafer (back grinding step); a step of singulating the semiconductor wafer to obtain bonding adhesive layer-attached semiconductor chips (singulation step); and a step of sticking a semiconductor chip to a wiring circuit board, a semiconductor wafer, or another semiconductor chip, with a bonding adhesive layer interposed therebetween (bonding step). The method for producing a semiconductor device according to the present embodiment may include, after the bonding step, a step of curing the bonding adhesive layer and sealing at least a portion of connecting parts with the cured bonding adhesive layer (sealing step).

In the lamination step, the surface on the bonding adhesive layer side of the laminated film and the semiconductor wafer are stuck together, and a bonding adhesive layer, an adhesive layer, and a base material layer are laminated in this order on a conductor wafer. When the laminated film includes a base material film on the bonding adhesive layer, the base material film is peeled, and then lamination is performed.

In the back grinding step, a surface of the semiconductor wafer on the opposite side of the side on which the bonding adhesive layer and the like are stacked is polished to thin the semiconductor wafer.

In the singulation step, the polished surface side of the thinned semiconductor wafer is stuck to a dicing tape, the semiconductor wafer and the bonding adhesive layer are cut using a dicing device, and bonding adhesive layer-attached semiconductor chips each composed of a singulated semiconductor chip and the cut bonding adhesive layer are obtained. The back grinding tape composed of a base material layer and an adhesive layer is peeled from the bonding adhesive layer before dicing.

In the bonding step, a semiconductor chip and a wiring circuit board, a semiconductor chip and a semiconductor wafer, or a semiconductor chip and another semiconductor chip are connected, with a bonding adhesive layer interposed therebetween.

When the bonding step is a step of connecting a semiconductor chip (hereinafter, referred to as “first semiconductor chip”) and another semiconductor chip (hereinafter, referred to as “second semiconductor chip”) with a bonding adhesive layer interposed therebetween, the bonding step may include a step of arranging a plurality of second semiconductor chips on a stage, and a temporary fixing step of sequentially arranging a first semiconductor chip on each of the plurality of second semiconductor chips arranged on the stage, with a bonding adhesive layer interposed therebetween, while heating the stage to 60 to 155° C., to obtain a plurality of stacked bodies in which a second semiconductor chip, a bonding adhesive layer, and a first semiconductor chip are stacked in this order.

Furthermore, when the bonding step is a step of connecting a semiconductor chip and a wiring circuit board or a semiconductor chip and a semiconductor wafer, with a bonding adhesive layer interposed therebetween, the bonding step may include a step of arranging a wiring circuit board or a semiconductor wafer on a stage, and a temporary fixing step of sequentially arranging a plurality of semiconductor chips on the wiring circuit board or semiconductor wafer arranged on the stage, with a bonding adhesive layer interposed therebetween, while heating the stage at 60 to 155° C., to obtain stacked bodies in which a wiring circuit board, a bonding adhesive layer, and a plurality of semiconductor chips are stacked in this order, or stacked bodies in which a semiconductor wafer, a bonding adhesive layer, and a plurality of semiconductor chips are stacked in this order.

In the temporary fixing step, a bonding adhesive layer-attached semiconductor chip is picked up and suctioned to a pressure-bonding tool (pressure-bonding head) of a pressure-bonding machine to temporarily fix the bonding adhesive layer-attached semiconductor chip to a wiring circuit board, another semiconductor chip, or a semiconductor wafer.

In the temporary fixing step, alignment is needed to electrically connect the connecting parts to each other. Therefore, generally, a pressure-bonding machine such as flip-chip bonder is used.

When the pressure-bonding tool picks up a semiconductor chip for temporary fixing, it is preferable that the pressure-bonding tool is at a low temperature so that heat is not transferred to the bonding adhesive layer or the like on the semiconductor chip. Meanwhile, during pressure-bonding (temporary pressure-bonding), it is preferable that the semiconductor chip is heated to a high temperature so as to increase fluidity of the bonding adhesive layer and efficiently eliminate any trapped voids. However, heating at a temperature lower than the initiation temperature of the curing reaction of the bonding adhesive layer is preferable. In order to shorten the cooling time, it is preferable that the difference between the temperature of the pressure-bonding tool at the time of picking up the semiconductor chip and the temperature of the pressure-bonding tool at the time of temporary fixing is smaller. This temperature difference is preferably 100° C. or less, more preferably 60° C. or less, and even more preferably substantially 0° C. When the temperature difference is 100° C. or more, productivity tends to decrease because cooling of the pressure-bonding tool takes time. The initiation temperature of the curing reaction of the bonding adhesive layer refers to the onset temperature when measurement is made using a DSC (manufactured by Perkin Elmer, Inc., DSC-Pyirs 1) under the conditions of a sample amount of 10 mg, a temperature increase rate of 10° C./min, and an air or nitrogen atmosphere.

The load to be applied for temporary fixing is appropriately set in consideration of controlling the number of connecting parts, the absorption of variations in height of the connecting parts, the amount of deformation of the connecting parts, and the like. In the temporary fixing step, it is preferable that after pressure-bonding (temporary pressure-bonding), the connecting parts that face each other are in contact. When the connecting parts are in contact after pressure-bonding, a metal joint of the connecting parts is likely to be formed in pressure-bonding in the sealing step (main pressure-bonding), and trapping of the bonding adhesive layer tends to occur less. It is preferable that the load is larger in order to eliminate voids and ensure contact of the connecting parts, and for example, the load is preferably 0.0001 to 0.2 N, more preferably 0.009 to 0.2 N, and even more preferably 0.001 to 0.1 N, per one connecting part (for example, a bump).

It is more preferable that the pressure-bonding time in the temporary fixing step is shorter from the viewpoint of improving productivity, and for example, the pressure-bonding time may be 5 seconds or less, 3 seconds or less, or 2 seconds or less.

The heating temperature of the stage is a temperature lower than the melting point of the connecting part, and may be usually 60 to 155° C., 65 to 120° C., or 70 to 100° C. By heating at such a temperature, voids trapped in the bonding adhesive layer can be efficiently eliminated. It should be noted that the heating temperature of the stage is not actually applied to the bonding adhesive layer itself.

It is preferable that the temperature of the pressure-bonding tool at the time of temporary fixing is set such that the temperature difference between that temperature and the temperature of the pressure-bonding tool at the time of picking up the semiconductor chips as described above becomes small; however, for example, the temperature at the time of temporary fixing may be 80 to 350° C., or 100 to 170° C.

When the bonding step includes the above-described temporary fixing step, in the sealing step following the temporary fixing step, the bonding adhesive layer in a plurality of stacked bodies or a stacked body including a plurality of semiconductor chips may be cured collectively or in divided parts, and a plurality of connecting parts may be sealed collectively or in divided parts. Through the sealing step, connecting parts facing each other are joined by metal bonding, and at the same time, voids between the connecting parts are usually filled by the bonding adhesive layer. The sealing step is carried out using an apparatus capable of heating to a temperature equal to or higher than the melting point of the metal of the connecting parts and capable of pressurization. Examples of the apparatus include a pressure reflow furnace and a pressure oven.

Regarding the heating temperature (connection temperature) in the sealing step, it is preferable to perform heating at a temperature equal to or higher than the melting point of the metal of at least one of the connecting parts facing each other (for example, bump-bump, bump-pad, or bump-wiring line). When the metal of the connecting parts is solder, the heating temperature is preferably 200° C. or higher and 450° C. or lower. When the heating temperature is a low temperature, the metal of the connecting parts does not melt, and there is a possibility that sufficient metal bonding may not be formed. When the heating temperature is an excessively high temperature, the effect of suppressing voids tends to become relatively small, or solder tends to scatter easily.

When pressurization for joining of the connecting parts is carried out using a pressure-bonding machine, since it is difficult for the heat of the pressure-bonding machine to be transferred to the bonding adhesive layer (fillet) overflowing from the lateral sides of the connecting part, after pressure-bonding (main pressure-bonding), a heating treatment for sufficiently carrying out curing of the bonding adhesive layer is often further required. Therefore, it is preferable that the pressure-bonding in the sealing step is carried out by applying air pressure in a pressure reflow furnace, a pressure oven, or the like, rather than by using a pressure-bonding machine. When pressure is applied by air pressure, heat can be applied to the entire system, the heating treatment after pressure-bonding (main pressure-bonding) can be shortened or omitted, and productivity is improved. Furthermore, when pressure is applied by air pressure, it is easy to perform main pressure-bonding of a plurality of stacked bodies (temporarily fixed bodies) or a stacked body (temporarily fixed body) including a plurality of temporarily fixed semiconductor chips in a batch manner. In addition, pressurization by air pressure is preferred instead of direct pressurization using a pressure-bonding machine, even from the viewpoint of suppressing fillet. Fillet suppression is important for the tendency toward miniaturization and density increase of the semiconductor device.

The atmosphere in which pressure-bonding in the sealing step is not particularly limited; however, an atmosphere containing air, nitrogen, formic acid, or the like is preferable.

The pressure for the pressure-bonding in the sealing step is appropriately set in accordance with the size, number, and the like of the members to be connected. The pressure may be, for example, higher than the atmospheric pressure and 1 MPa or lower. A higher pressure is more preferable from the viewpoint of suppressing voids and improving connectivity, and from the viewpoint of suppressing fillet, a lower pressure is more preferable. Therefore, the pressure is more preferably 0.05 to 0.5 MPa.

The pressure-bonding time varies depending on the constituent metal of the connecting part; however, from the viewpoint of improving productivity, a shorter time is more preferable. When the connecting part is solder bumps, the connection time is preferably 20 seconds or less, more preferably 10 seconds or less, and even more preferably 5 seconds or less. In the case of metal connection of copper-copper or copper-gold, the connection time is preferably 60 seconds or less.

When a plurality of semiconductor chips are three-dimensionally stacked as in the case of a semiconductor device having a TSV structure, a semiconductor device may be obtained by stacking a plurality of semiconductor chips one by one into a temporarily fixed state, and then heating and pressurizing the plurality of stacked semiconductor chips in a batch manner.

### EXAMPLES

Hereinafter, the present disclosure will be described more specifically by way of Examples; however, the present disclosure is not intended to be limited to the Examples.

The compounds used in each of Examples and Comparative Examples are as follows.

Component (a): Thermoplastic resin
Phenoxy resin (manufactured by NIPPON STEEL Chemical & Material Co., Ltd., trade name “FX293”, Tg: about 160° C., Mw: about 30000, biphenyl fluorene type phenoxy resin)
   Component (b): Thermosetting resin
Bisphenol F type liquid epoxy resin (manufactured by Mitsubishi Chemical Corporation, trade name “YL983U”)
Liquid epoxy resin (manufactured by Mitsubishi Chemical Corporation, trade name “YX7110B80”)
Triphenolmethane skeleton-containing polyfunctional solid epoxy resin (manufactured by Mitsubishi Chemical Corporation, trade name “EP1032H60”)
   Component (c): Curing agent
Imidazole-based curing agent (manufactured by SHIKOKU CHEMICALS CORPORATION, trade name “2PHZ-PW”, 2-phenyl-4,5-dihydroxymethylimidazole)
   Component (d): Flux compound
Glutaric acid (manufactured by FUJIFILM Wako Pure Chemical Corporation, melting point: 98° C., molecular weight: 132, compound having a number of main chain-constituting atoms (carbon atoms) of 3)
Adipic acid (manufactured by FUJIFILM Wako Pure Chemical Corporation, melting point: 152° C., molecular weight: 146, compound having a number of main chain-constituting atoms (carbon atoms) of 4)
Pimelic acid (manufactured by FUJIFILM Wako Pure Chemical Corporation, melting point: 105° C., molecular weight: 160, compound having a number of main chain-constituting atoms (carbon atoms) of 5)
Suberic acid (manufactured by FUJIFILM Wako Pure Chemical Corporation, melting point: 142° C., molecular weight: 174, compound having a number of main chain-constituting atoms (carbon atoms) of 6)
Azelaic acid (manufactured by FUJIFILM Wako Pure Chemical Corporation, melting point: 98° C., molecular weight: 188, compound having a number of main chain-constituting atoms (carbon atoms) of 7)
Sebacic acid (manufactured by FUJIFILM Wako Pure Chemical Corporation, melting point: 135° C., molecular weight: 202, compound having a number of main chain-constituting atoms (carbon atoms) of 8)
Undecanedioic acid (manufactured by Tokyo Chemical Industry Co., Ltd., melting point: 109° C., molecular weight: 216, compound having a number of main chain-constituting atoms (carbon atoms) of 9)
Thapsic acid (manufactured by Tokyo Chemical Industry Co., Ltd., melting point: 126° C., molecular weight: 286, compound having a number of main chain-constituting atoms (carbon atoms) of 14)
Phthalic acid (manufactured by FUJIFILM Wako Pure Chemical Corporation, melting point: 210° C., molecular weight: 166, compound having an aromatic ring)
Isophthalic acid (manufactured by FUJIFILM Wako Pure chemical Corporation, melting point: 350° C., molecular weight: 166, compound having an aromatic ring)
1,3-Cyclohexanedicarboxylic acid (cis-, trans-mixture) (manufactured by Tokyo Chemical Industry Co., Ltd., melting point: 136° C., molecular weight: 172, compound having an aliphatic ring) Component (e): Filler
Acrylic rubber particles (organic filler, manufactured by DOW Inc., trade name “EXL2655”)
Methacrylic surface-treated silica filler (inorganic filler, manufactured by ADMATECHS COMPANY LIMITED, trade name “KE180G-HLA”, average particle size: about 180 nm)

The weight average molecular weight (Mw) of the component (a) was determined by a GPC method. The details of the GPC method are as follows.
Apparatus name: HPLC-8020 (product name, manufactured by Tosoh Corporation)
Column: 2 pieces of GMHXL+1 piece of G-2000XL
Detector: RI detector
Column temperature: 35° C.
Flow rate: 1 mL/min
Standard substance: Polystyrene

### Examples 1 to 8 and Comparative Examples 1 to 3

### <Production of Film-Shaped Adhesive (Bonding Adhesive Layer)>

A thermoplastic resin, a thermosetting resin, a curing agent, a flux compound, and a filler in the blending amounts (unit: parts by mass) shown in Table 1 were added to an organic solvent (cyclohexanone) such that the NV value ([mass of coating material portion after drying]/[mass of coating material portion before drying]×100) would be 50%. Thereafter, zirconia beads having a diameter of ϕ1.0 mm and zirconia beads having a diameter of ϕ2.0 mm of the same mass as the blending amount of the solid content (thermoplastic resin, thermosetting resin, curing agent, flux compound, and filler) were added to the same container, and the mixture was stirred for 30 minutes in a ball mill (Fritsch Japan Co., Ltd., trade name “Planetary Type Micropulverizer P-7”). After the stirring, the zirconia beads were removed by filtration, and a coating varnish was produced.

The obtained coating varnish was applied on a base material film (manufactured by Teijin Film Solutions Limited, trade name “PUREX A55”) using a small-sized precision coating apparatus (manufactured by Yasui Seiki Company, Ltd.) and dried (100° C./10 min) in a clean oven (manufactured by ESPEC CORP.) to obtain a film-shaped adhesive (bonding adhesive layer) having a film thickness of 10 μm.

### <Production of Back Grinding Tape (Pressure-Sensitive Adhesive Tape)>

An acrylic copolymer that used 2-ethylhexyl acrylate and methyl methacrylate as main monomers and used hydroxyethyl acrylate and acrylic acid as functional group monomers, was obtained by a solution polymerization method. The weight average molecular weight of this synthesized acrylic copolymer was 400000, and the glass transition point was −38° C. 100 parts by mass of this acrylic copolymer was blended with a polyfunctional isocyanate crosslinking agent (manufactured by Nippon Polyurethane Industry Co., Ltd., trade name “CORONATE HL”) in a proportion of 10 parts by mass, and a varnish for adhesive was prepared.

The above-described varnish for adhesive was applied on a polyethylene terephthalate (PET) base material (manufactured by UNITIKA LTD., trade name “EMBLET S25”) having a thickness of 25 μm using an applicator, while adjusting the gap, such that the thickness of the adhesive layer after drying would be 60 μm, and the varnish for adhesive was dried at 80° C. for 5 minutes. As a result, a back grinding tape in which a pressure-sensitive adhesive layer was formed on a base material layer was obtained.

### <Production of Laminated Film>

Next, the above-described back grinding tape composed of an adhesive layer and a base material layer was stuck onto the above-described bonding adhesive layer under the conditions of 60° C., a linear pressure of 3 kgf, and a rate of 5 m/min such that the bonding adhesive layer and the adhesive layer were in contact, and a laminated film having a laminated structure of base material film/bonding adhesive layer/adhesive layer/base material layer was obtained.

### [Evaluation]

Methods for evaluating the laminated films obtained in Examples and Comparative Examples are shown below. The evaluation results are shown in Table 1 or Table 2.

### <Measurement of Rate of Change Over Time of Flux Agent>

The laminated films obtained in Examples and Comparative Examples were left to stand in a room temperature environment (23° C., 50% RH) for 4 weeks, and laminated films after being left to stand for 4 weeks were obtained. For the laminated films before and after being left to stand for 4 weeks, the rate of change over time in the amount of the flux agent present in the bonding adhesive layer was determined by the following method.

The bonding adhesive layer obtained by peeling the back grinding tape and the base material film from a laminated film was cut into a size of 1.0 cm×1.0 cm to obtain a sample, and the FT-IR spectrum of this sample surface was measured using an ALPHA compact infrared spectrometer (manufactured by Bruker Optics, ATR method). In the obtained FT-IR spectrum, the peak intensity of the flux agent in the bonding adhesive layer before being left to stand for 4 weeks was referred to as a, the peak intensity of the flux agent in the bonding adhesive layer after being left to stand for 4 weeks was referred to as b, and the rate of change over time (%) was calculated by the following formula. Incidentally, the peak intensities a and b are values determined by adjusting a reference peak that does not change over time, which is different from the peak of the flux agent, to have the same intensity before and after being left to stand for 4 weeks.

Rate of change over time(%)=((b−a)/a)×100

### <Measurement of Wetting Rate>

The laminated films obtained in Examples and Comparative Examples were left to stand in a room temperature environment (23° C., 50% RH) for 4 weeks, and laminated films after being left to stand for 4 weeks were obtained. For the laminated films before and after being left to stand for 4 weeks, the wetting rate was measured by the following method.

The bonding adhesive layer was obtained by peeling the back grinding tape and the base material film from a laminated film, four sheets of the bonding adhesive layer were laminated using a tabletop laminator (product name “Hotdog GK-13DX”, manufactured by Lami Corporation Inc.) to have a film thickness of 40 μm, subsequently the laminate was cut into a square having a size of 7.5 mm on each side, and this was stuck onto a plurality of solder bump-attached semiconductor chip (chip size: 7.3 mm×7.3 mm, thickness 0.1 mm, bump (connecting part) height: about 45 μm (sum of copper pillar and solder), number of bumps: 1048 pins, pitch 80 μm, product name “WALTS-TEG CC80”, manufactured by WALTS CO., LTD.) at 80° C. The semiconductor chip to which the bonding adhesive layer was attached was sequentially pressure-bonded other semiconductor chips (chip size: 17 mm×17 mm, thickness 0.356 mm, number of bumps: 1048 pins, pitch 80 μm, product name: WALTS-KIT CC80, manufactured by WALTS CO., LTD.) by heating and pressurizing with a flip-chip bonder (FCB3, manufactured by Panasonic Corporation), and a stacked body after pressure-bonding (mounted sample for evaluation) was obtained. Regarding the conditions for pressure-bonding, temporary pressure-bonding was performed while applying heat at 80° C./30 N/1 second (set heating-up time at the time of heating-up: 0.1 seconds), and then main pressure-bonding was performed in a state in which a pressure of 30 N was applied, by raising temperature from 80° C. to 200° C. over 2 seconds, raising temperature from 200° C. to 300° C. over 15 seconds, maintaining temperature at 300° C. for 1 second, and then lowering temperature from 300° C. to 200° C. over 2 seconds.

The obtained mounting sample for evaluation was polished using a tabletop polishing machine (Refine Polisher, manufactured by Refine Tec Ltd.) until the bump connected portion present inside the chip was exposed. As the waterproof abrasive paper used for polishing, one having a size of 200 cmϕ and a granularity of 1000 was initially used, subsequently the waterproof abrasive paper was re-covered with one having a granularity of 2000, and then polishing was continued until the connected portion was exposed. The exposed bump connected portion was observed with an SEM (trade name “TM3030Plus tabletop microscope”, manufactured by Hitachi High-Tech Co., Ltd.), and the wetting rate of solder to the top surface of Cu wiring lines (ratio of the width of solder in contact with the top surface of Cu wiring lines with respect to the width of the top surface of Cu wiring lines in an SEM cross-sectional image) was measured. The wetting rate was taken as the average value of the values measured at 20 sites. Furthermore, the decrease rate (((A-B)/A)×100) of the wetting rate B in the case of using the laminated film after being left to stand for 4 weeks with respect to the wetting rate A in the case of using the laminated film before being left to stand for 4 weeks (initial) was determined.

### <Evaluation of Connectivity>

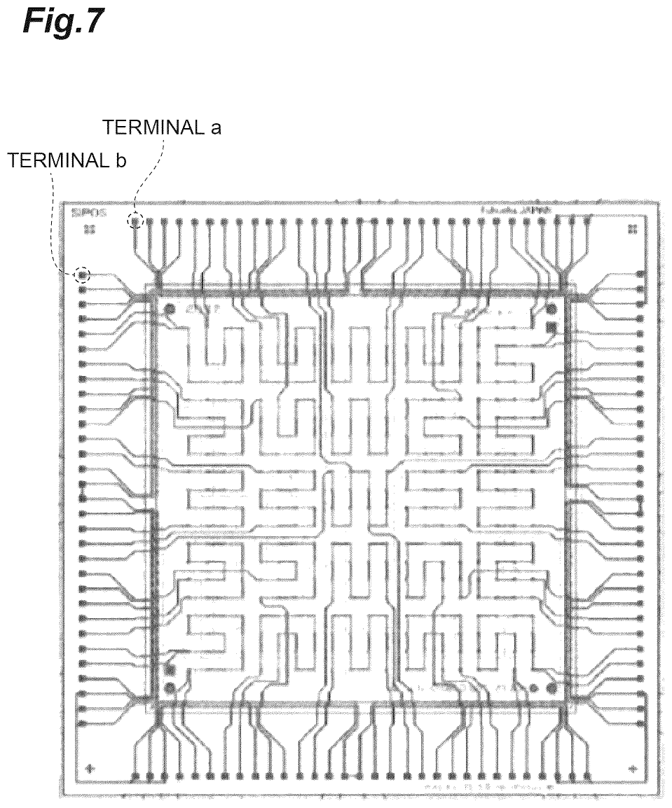

For the mounting samples for evaluation of Examples 1 to 3 and 8 and Comparative Examples 1 to 3 produced for the above-described measurement of wetting rate, connectivity was evaluated by measuring the resistance value of the inner periphery of the chip using a circuit tester (trade name “POCKET TESTER 4300 COUNT”, manufactured by CUSTOM Co., Ltd.). The circuit diagram of the lower chip (chip size: 17 mm×17 mm, thickness 0.356 mm, number of bumps: 1048 pins, pitch 80 μm, product name “WALTS-KIT CC80”, manufactured by WALTS CO., LTD.) used for mounting is shown in FIG. 7. In this circuit, the resistance value between terminal a and terminal b in the figure is the resistance value of the inner periphery of the chip. When the value of this resistance value is less than 35Ω, it indicates satisfactory connection, and when the resistance value is 35Ω or greater or the resistance value cannot be measured, it indicates connection failure. The measurement results of the resistance value are shown in Table 2, and the symbol “-” in the table means that the resistance value could not be measured.

<¹H-NMR measurement>

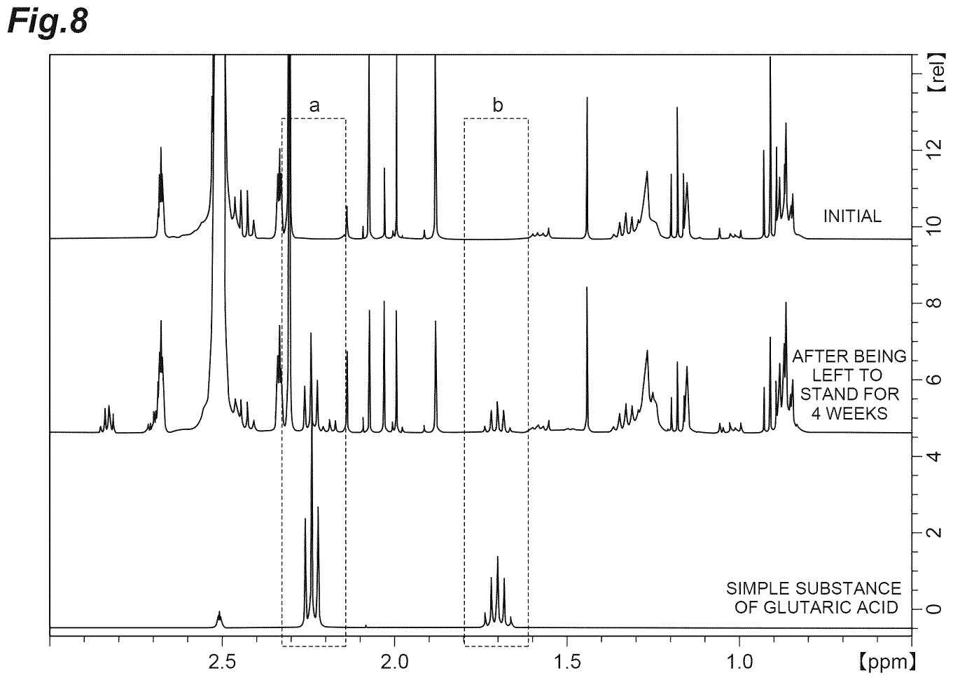

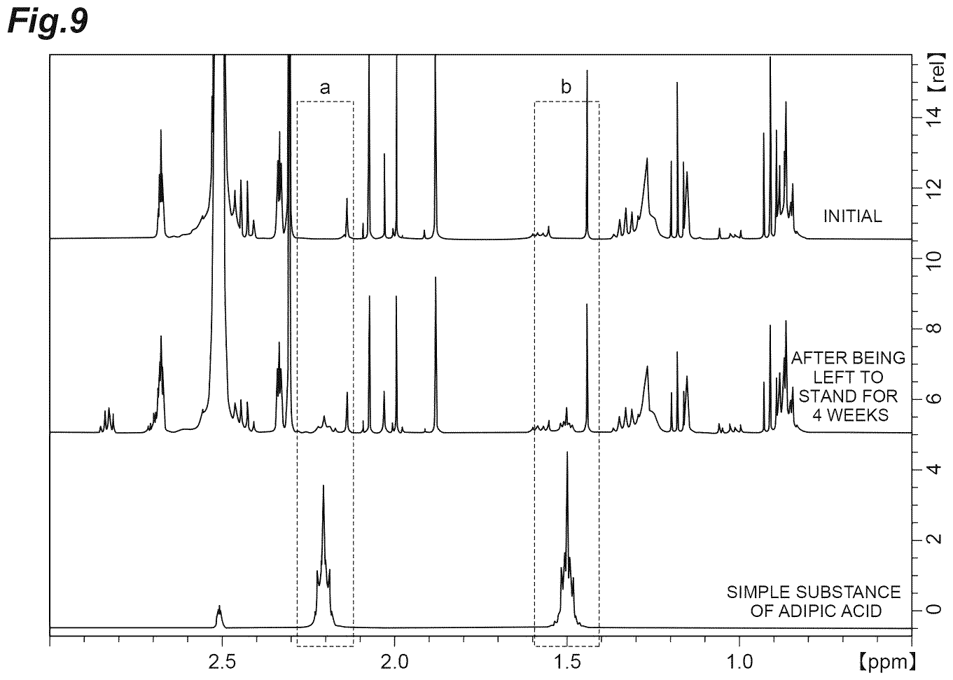

The laminated films obtained in Example 1 and Comparative Example 1 were left to stand in a room temperature environment (23° C., 50% RH) for 4 weeks, and laminated films after being left to stand for 4 weeks were obtained. The back grinding tape (BGT) was peeled from the laminated films before and after being left to stand for 4 weeks, and the obtained BGT was immersed in dimethyl sulfoxide-d6 at 25° C. for 2 hours to extract components. Therefore, the supernatant was collected, and a BGT extract was obtained. For the BGT extract obtained from the initial laminated film (hereinafter, also referred to as “initial BGT extract”), the BGT extract obtained from the laminated film after being left to stand for 4 weeks (hereinafter, also referred to as “BGT extract after being left to stand for 4 weeks”), and the flux compounds (glutaric acid and adipic acid) used in Example 1 and Comparative Example 1, respectively, nuclear magnetic resonance (1H-NMR) measurement was performed. The measurement conditions are as follows. The obtained ¹H-NMR spectra are shown in FIG. 8 (Comparative Example 1) and FIG. 9 (Example 1).
Measurement apparatus: Bruker Biospin ADVANCE NEO 400 MHz+CryoProbe (manufactured by Bruker)
Observed nucleus: ¹H
Resonance frequency: 400 MHZ
Measurement temperature: 25° C.
Solvent: Dimethyl sulfoxide-d6, 99.9% (containing 0.05 vol % TMS) Reference material: Tetramethylsilane

As shown in FIG. 8, from a comparison between the 1H-NMR spectra of the initial BGT extract of Comparative Example 1, the BGT extract after being left to stand for 4 weeks of Comparative Example 1, and glutaric acid, the peaks within the frames of a and b observed from simple substance of glutaric acid were not observed in the initial BGT extract but were observed in the BGT extract after being left to stand for 4 weeks. From this, it is understood that when the laminated film is left to stand in a room temperature environment for a long period of time, glutaric acid migrates from the bonding adhesive layer to the adhesive layer. On the other hand, as shown in FIG. 9, from a comparison between the ¹H-NMR spectra of the initial BGT extract of Example 1, the BGT extract after being left to stand for 4 weeks of Example 1, and adipic acid, the peaks within the frames of a and b observed from simple substance of adipic acid were not observed in the initial BGT extract and were also hardly observed in the BGT extract after being left to stand for 4 weeks. From this, it is understood that as compared with glutaric acid, even when the laminated film is left to stand in a room temperature environment for a long period of time, migration of adipic acid from the bonding adhesive layer to the adhesive layer is suppressed.

TABLE 1

| | | Example | | | | | | | | Comparative Example | | |
|---|---|---|---|---|---|---|---|---|---|---|---|---|
| | | 1 | 2 | 3 | 4 | 5 | 6 | 7 | 8 | 1 | 2 | 3 |
| Component (a) | FX-293 | 20 | 20 | 20 | 20 | 20 | 20 | 20 | 20 | 20 | 20 | 20 |
| Component (b) | YL983U | 15 | 15 | 15 | 15 | 15 | 15 | 15 | 15 | 15 | 15 | 15 |
| | YX7110B80 | 5 | 5 | 5 | 5 | 5 | 5 | 5 | 5 | 5 | 5 | 5 |
| | EP1032H60 | 45 | 45 | 45 | 45 | 45 | 45 | 45 | 45 | 45 | 45 | 45 |
| Component (c) | 2PHZ-PW | 3 | 3 | 3 | 3 | 3 | 3 | 3 | 3 | 3 | 3 | 3 |
| Component (d) | Glutaric | — | — | — | — | — | — | — | — | 2.0 | — | — |
| | acid (C3) | | | | | | | | | | | |
| | Adipic | 2.2 | — | — | — | — | — | — | — | — | — | — |
| | acid (C4) | | | | | | | | | | | |
| | Pimelic | — | — | — | — | — | — | — | — | — | 2.4 | — |
| | acid (C5) | | | | | | | | | | | |
| | Suberic | — | 2.6 | — | — | — | — | — | — | — | — | — |
| | acid (C6) | | | | | | | | | | | |
| | Azelaic | — | — | — | — | — | — | — | — | — | — | 2.8 |
| | acid (C7) | | | | | | | | | | | |
| | Sebacic | — | — | 3.1 | — | — | — | — | — | — | — | — |
| | acid (C8) | | | | | | | | | | | |
| | Undecanedioic | — | — | — | 3.3 | — | — | — | — | — | — | — |
| | acid (C9) | | | | | | | | | | | |
| | Thapsic | — | — | — | — | 4.3 | — | — | — | — | — | — |
| | acid (C14) | | | | | | | | | | | |
| | Phthalic | — | — | — | — | — | 2.5 | — | — | — | — | — |
| | acid | | | | | | | | | | | |
| | Isophthalic | — | — | — | — | — | — | 2.5 | — | — | — | — |
| | acid | | | | | | | | | | | |
| | 1,3- | — | — | — | — | — | — | — | 2.6 | — | — | — |
| | Cyclohexane- | | | | | | | | | | | |
| | dicarboxylic | | | | | | | | | | | |
| | acid | | | | | | | | | | | |
| Component (e) | EXL2655 | 10 | 10 | 10 | 10 | 10 | 10 | 10 | 10 | 10 | 10 | 10 |
| | KE180G-HLA | 65 | 65 | 65 | 65 | 65 | 65 | 65 | 65 | 65 | 65 | 65 |
| Molecular weight | | 146.14 | 174.19 | 202.24 | 216.27 | 286.41 | 166.13 | 166.13 | 172.18 | 132.11 | 160.17 | 188.22 |
| of component (d) | | | | | | | | | | | | |
| Melting point | | 152 | 142 | 135 | 109 | 126 | 210 | 350 | 136 | 98 | 105 | 98 |
| of component (d) | | | | | | | | | | | | |
| pKa of | | 4.42 | 4.52 | 4.59 | 4.48 | 4.48 | 2.89 | 3.54 | 4.32 | 4.31 | 4.71 | 4.53 |
| component (d) | | | | | | | | | | | | |
| Rate of change | | 16 | 10 | 8 | — | 20 | 13 | 9 | −3 | −21 | −20 | −18 |
| over time (%) | | | | | | | | | | | | |
| Wetting | Initial | 93 | 98 | 98 | 99 | 99 | 70 | 75 | 98 | 98 | 99 | 98 |
| rate (%) | After being | 98 | 98 | 98 | 98 | 98 | 70 | 70 | 90 | 3 | 30 | 40 |
| | left to stand | | | | | | | | | | | |
| | for 4 weeks | | | | | | | | | | | |

| | | | | | | | | | | | |
|---|---|---|---|---|---|---|---|---|---|---|---|
| Decrease rate of | −5.4 | 0.0 | 0.0 | 1.0 | 1.0 | 0.0 | 6.7 | 8.2 | 96.9 | 69.7 | 59.2 |
| wetting rate (%) | | | | | | | | | | | |

TABLE 2

| | | Example | | | | Comparative Example | | |
|---|---|---|---|---|---|---|---|---|
| | | 1 | 2 | 3 | 8 | 1 | 2 | 3 |
| Resistance | Initial | 25 | 20 | 24 | 21 | 26 | 27 | 23 |
| value (Ω) | After being | 20 | 22 | 23 | 17 | — | — | — |
| | left to stand | | | | | | | |
| | for 4 weeks | | | | | | | |

### REFERENCE SIGNS LIST

1: bonding adhesive layer (film-shaped adhesive), 2: base material layer, 3: adhesive layer, 4: back grinding tape, 10: laminated film, 12: semiconductor chip, 14: substrate, 15: wiring line, 30: connecting bump, 34: through electrode, 40: bonding adhesive layer, 50: interposer, 100, 300, 500: semiconductor device.

1. A laminated film comprising, in the following order:
a bonding adhesive layer containing a thermoplastic resin, a thermosetting resin, a curing agent, and a flux compound having two carboxyl groups;
an adhesive layer; and
a base material layer,
wherein the flux compound includes at least one selected from the group consisting of a compound having an aromatic ring, a compound having an aliphatic ring, and a compound having a number of main chain-constituting atoms of 4, 6, or 8 or more.

2. The laminated film according to claim 1, wherein a number of main chain-constituting atoms of the compound having a number of main chain-constituting atoms of 4, 6, or 8 or more is 4, 6, or 8.

3. The laminated film according to claim 1, wherein the compound having a number of main chain-constituting atoms of 4, 6, or 8 or more includes a compound represented by the following general formula (1): 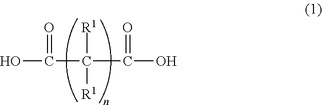
wherein R¹ represents a hydrogen atom or a monovalent organic group; n represents an integer of 4, 6, or 8 to 14; and a plurality of R¹'s existing therein may be identical with or different from each other.

4. The laminated film according to claim 1, wherein the compound having a number of main chain-constituting atoms of 4, 6, or 8 or more includes a compound represented by the following general formula (2): 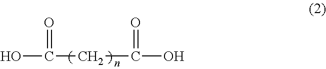
wherein n represents an integer of 4, 6, or 8 to 14.

5. The laminated film according to claim 1, wherein the flux compound has a melting point of 100 to 160° C.

6. The laminated film according to claim 1, wherein the thermosetting resin includes an epoxy resin.

7. The laminated film according to claim 1, wherein the curing agent includes an amine-based curing agent.

8. The laminated film according to claim 1, wherein the curing agent includes an imidazole-based curing agent.

9. A method for producing a semiconductor device in which connecting parts of a semiconductor chip and a wiring circuit board are electrically connected to each other, or a semiconductor device in which respective connecting parts of a plurality of semiconductor chips are electrically connected to each other, the method comprising:
sticking a surface on the bonding adhesive layer side of the laminated film according to claim 1 and a semiconductor wafer together;
back grinding the semiconductor wafer;
singulating the semiconductor wafer to obtain a bonding adhesive layer-attached semiconductor chip; and
sticking the semiconductor chip to a wiring circuit board, a semiconductor wafer, or another semiconductor chip, with the bonding adhesive layer interposed therebetween.

10. The method for producing a semiconductor device according to claim 9, wherein said sticking the semiconductor chip comprises:
arranging a plurality of the other semiconductor chips on a stage; and
sequentially arranging the semiconductor chip on each of the plurality of the other semiconductor chips arranged on the stage, with the bonding adhesive layer interposed therebetween, while heating the stage to 60 to 155° C., and obtaining a plurality of stacked bodies in which the other semiconductor chip, the bonding adhesive layer, and the semiconductor chip are stacked in this order.

11. The method for producing a semiconductor device according to claim 9, wherein said sticking the semiconductor chip comprises:
arranging the wiring circuit board or the semiconductor wafer on a stage; and
sequentially arranging a plurality of the semiconductor chips on the wiring circuit board or semiconductor wafer arranged on the stage, with the bonding adhesive layer interposed therebetween, while heating the stage to 60 to 155° C., and obtaining a stacked body in which the wiring circuit board, the bonding adhesive layer, and a plurality of the semiconductor chips are stacked in this order, or a stacked body in which the semiconductor wafer, the bonding adhesive layer, and a plurality of the semiconductor chips are stacked in this order.
